(19) United States
(12) Patent Application Publication
(10) Pub. No.: US 2007/0159210 A1
(43) Pub. Date: Jul. 12, 2007

(54) Operation mode setting circuit, LSI having operation mode setting circuit, and operation mode setting method

(75) Inventor: Makoto Sato, Hino-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/642,653

(22) Filed: Dec. 21, 2006

(30) Foreign Application Priority Data
Dec. 23, 2005 (JP) 2005-371130

(51) Int. Cl. H03K 19/00

(52) U.S. Cl. 326/16

(57) ABSTRACT

According to one embodiment, a logical circuit performs an AND operation based on a mode signal input via a mode terminal and a signal formed by delaying a system reset signal as much as one clock during system reset. The logical circuit outputs a signal indicating a usual operation mode for a predetermined period in response to the system reset signal, and outputs a value of the input mode signal after the predetermined period. This mode signal is held by a selector and a flip-flop, and output to an LSI main body unit.

### CROSS-REFERENCE TO RELATED APPLICATIONS

This application is based upon and claims the benefit of priority from Japanese Patent Application No. 2005-371130, filed Dec. 23, 2005, the entire contents of which are incorporated herein by reference.

### BACKGROUND

1. Field

One embodiment of the invention relates to a technology to perform an operation test of an LSI without disposing any exclusive terminal for a test mode.

2. Description of the Related Art

An operation test of a large scale integrated circuit (LSI) such as a microprocessor unit (MPU) or a memory is performed in detail before the LSI is shipped as a product. This operation test is performed for each circuit block constituting the LSI which has been set to a test mode.

In general, an input/output state of an external connection terminal in the test mode is set so as to be largely different from that of a usual mode. To bring the LSI into the test mode, for example, an exclusive terminal for setting the test mode is used. When this exclusive terminal is set to a high (H) level voltage or a low (L) level voltage, the test mode/the usual operation mode is set.

In recent years, functions of the LSI have increased more and more. In consequence, the number of terminals disposed on the LSI has increased. Therefore, a technology to set the LSI to the test mode without disposing any test mode terminal required only for the operation test of the LSI is disclosed in, for example, Japanese Patent Application KOKAI Publication No. 2003-273232. In this publication, a terminal for use in a usual operation is used as the terminal for setting the test mode.

In the above publication, the terminal usable as the terminal for setting the test mode is limited to a terminal for a specific application such as a terminal which selects a start program during reset of a microcomputer.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram showing a constitution of an LSI operation mode setting circuit 100 according to the present invention;

FIG. 2A is a circuit block diagram showing a main constitution extracted from the LSI operation mode setting circuit 100 of FIG. 1;

FIG. 2B is a timing chart showing waveforms of specific signals (#201 to #204) of FIG. 2A;

FIG. 3 is a diagram showing one example of an operation mode set to an LSI 300; and

FIG. 4 is a diagram showing a behavior in which a potential of a certain terminal TAj of a terminal group TG changes, after a system reset signal has become active.

### DETAILED DESCRIPTION

Various embodiments according to the invention will be described hereinafter with reference to the accompanying drawings. In general, according to one embodiment of the invention, there is provided a mode setting circuit which sets an operation mode of an LSI and which is disposed in the same chip as that of the LSI, the mode setting circuit comprising a first delay circuit which delays a system reset signal as much as one cycle of a clock signal; a second delay circuit which delays the system reset signal as much as two cycles of the clock signals; a mode terminal which inputs a mode signal indicating one of a usual operation mode and a test mode during system reset; a logical circuit which performs a logical operation based on the mode signal input via the mode terminal and the system reset signal input into the first delay circuit; a setting circuit which sets input/output of the mode terminal based on the system reset signal and an output signal of the second delay circuit; a selection circuit having first and second input terminals, an output signal of the logical circuit being input into the first input terminal, the selection circuit being configured to select one of signals input into the first and second input terminals based on an output signal of the first delay circuit; and a holding circuit which holds the signal selected by the selection circuit based on the clock signal and which supplies the held signal to the second input terminal of the selection circuit and which supplies the held signal as the mode signal to an LSI main body.

According to the mode setting circuit, there is provided an LSI operation mode setting circuit capable of setting the test mode/the usual operation mode of the LSI by use of a terminal for general application without disposing any exclusive test mode setting terminal.

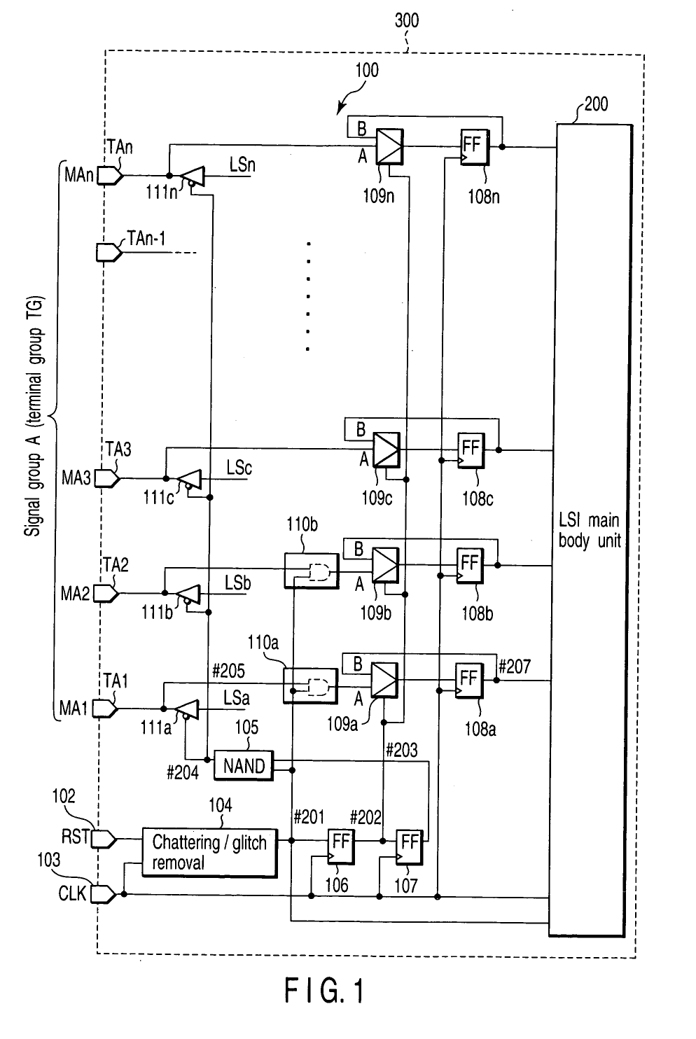

FIG. 1 is a block diagram showing a constitutional example of an LSI operation mode setting circuit 100 according to the present invention. This LSI test mode setting circuit 100 is a circuit disposed in an LSI 300, and disposed together with, for example, an LSI main body unit 200 on one chip. As the LSI main body unit, there is used an integrated circuit such as an MPU or a memory.

A signal group A indicates signals output from a terminal group TG (TA1 to TAn) during a usual operation, or operation mode setting input signals (described later) which are input from the outside of the chip into the terminal group TG, when a system reset signal RST is at an active level, that is, during system reset. It is to be noted that in FIG. 1, other external terminals connected to the LSI main body unit 200 of the LSI 300 are omitted.

The terminals TA1 to TAn of the terminal group TG are provided with buffers 111a to 111n, selectors 109a to 109n and flip-flops (FFs) 108a to 108n, respectively. Among these terminals, the terminals TA1, TA2 are further provided with logical circuits 110a, 110b. Into the buffers 111a to 111n, signals LSa to LSn are directly input from the LSI main body unit 200, respectively.

A terminal 102 is an input terminal of the system reset signal RST, and a terminal 103 is an input terminal of a system clock signal CLK. In the present embodiment, the system reset signal RST will be described as a low active signal.

A chattering/glitch removal circuit 104 is a circuit for removing an unstable potential such as chattering or glitch from the system reset signal RST. When a potential level (H/L) of the input system reset signal RST is continuously constant for a predetermined clock period, the chattering/glitch removal circuit 104 outputs the level. Furthermore, the chattering/glitch removal circuit 104 generates the system reset signal in synchronization with the clock signal CLK. An operation of the chattering/glitch removal circuit 104 is referred to as synchronization of the reset.

A flip-flop 106 holds an output signal #201 of the chattering/glitch removal circuit 104 at a rising edge of the system clock signal CLK, and outputs the held signal. A flip-flop 107 holds an output signal #202 of the flip-flop at the rising edge of the system clock signal CLK, and outputs the held signal. Therefore, the flip-flop 106 generates a signal in which the system reset signal #201 synchronized by the chattering/glitch removal circuit 104 is delayed as much as one clock cycle, and the flip-flop 107 generates a signal #203 in which the system reset signal #201 is delayed as much as two clock cycles.

When both of the output signal #201 of the chattering/glitch removal circuit 104 and the output signal #203 of the flip-flop 107 are at an H level, an NAND circuit 105 generates an L level signal as an output signal #204. When the output signal #204 of the NAND circuit 105 is at the H level, output terminals of the buffers 111a to 111n have high impedances. That is, the NAND circuit 105 controls input/output directions of the terminals TA1 to TAn.

The logical circuits 110a, 110b are combined circuits, and logics and the number of the circuits to be used are determined in accordance with specifications of the LSIs. In the present embodiment, the logical circuits 110a, 110b correspond to AND circuits. That is, the logical circuit 110a outputs a value of an input signal #205 as it is, when the input signal #201 is at the H level. An operation of the logical circuit 110b is the same as in the case of the logical circuit 110a.

The selectors 109a to 109n select signals on input A sides (operation mode setting signals) during reset (at a time when the signal #203 is at the L level), and select signals on input B sides (signals held by the flip-flops 108a to 108n) after the reset has been cancelled. The flip-flops 108a to 108n are provided to hold the operation mode selected by the selectors 109a to 109n as described later.

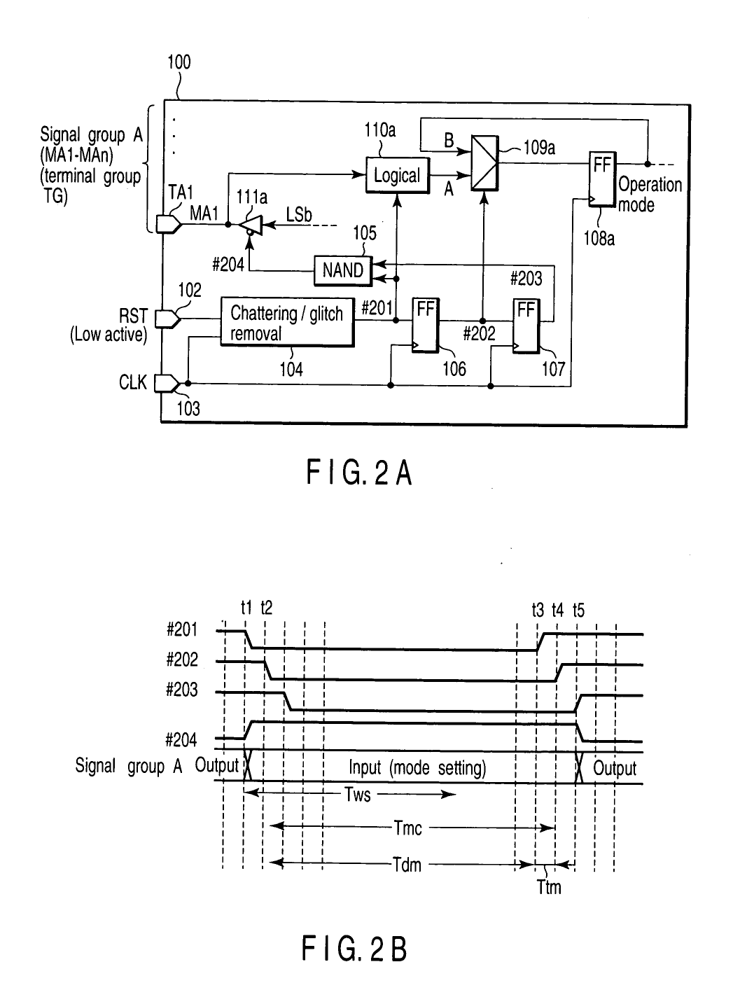

FIG. 2A is a circuit block diagram showing a main constitution extracted from the LSI operation mode setting circuit 100 of FIG. 1 to describe a basic operation of the present invention. FIG. 2B is a timing chart showing waveforms of specific signals (#201 to #204) of FIG. 2A. The circuit elements 111b, 110b, 109b and 108b for the terminal TA2 which is not shown in FIG. 2A operate in the same manner as in the circuit elements 111a, 110a, 109a and 108a. Therefore, the description of operations of these circuit elements 111b, 110b, 109b and 108b is omitted hereinafter.

The signal #201 is a synchronized system reset signal, and is at the L level for a period of time t1 to t3 in FIG. 2B. The signals #202, #203 are signals formed by delaying the signal #201 as much as one cycle and two cycles, respectively. The signal #204 is a signal formed by an NAND logical operation of the signals #201 and #203. For a period (t1 to t5) for which this signal #204 is at the H level, the terminal group TG is in an input state of the mode setting signal.

For a period Tmc for which the signal #202 is at the L level, the operation mode can be updated. Specifically, for the period Tmc (t2 to t4) for which the #202 is at the L level, the input A side of the selector 109a is selected. At this time, a signal MA1 in a signal group A is calculated by the logical circuit 110a, and an operation result is input into the flip-flop 108a through the selector 109a. For the period for which the signal #202 is at the H level, the input B side of the selector 109a is selected.

Characteristics of the present embodiment reside in that a timing t4 when the selection control signal #202 of the selector 109a changes to the H level is after one cycle has elapsed from a time when one input signal #201 of the logical circuit 111a changes to the H level at a time t3.

Since the logical circuit 110a is set to an AND logic in the present embodiment, the logical circuit 110a surely outputs the L level for a period (t1 to t3) for which the signal #201 is at the L level. When the signal #201 becomes the H level at the time t3, the logical circuit 110a outputs a signal having a level equal to that of the input signal MA1. At the time t4, the signal #202 becomes the H level, but simultaneously the value selected (output) by the selector 109a till this time is held by the flip-flop 108a. Afterward, the value output from the flip-flop 108a is fed back to the flip-flop 108a via the selector 109a, and until the system reset signal RST becomes the active level, the above value is output from the flip-flop 108a while the level held at the time t4 is kept.

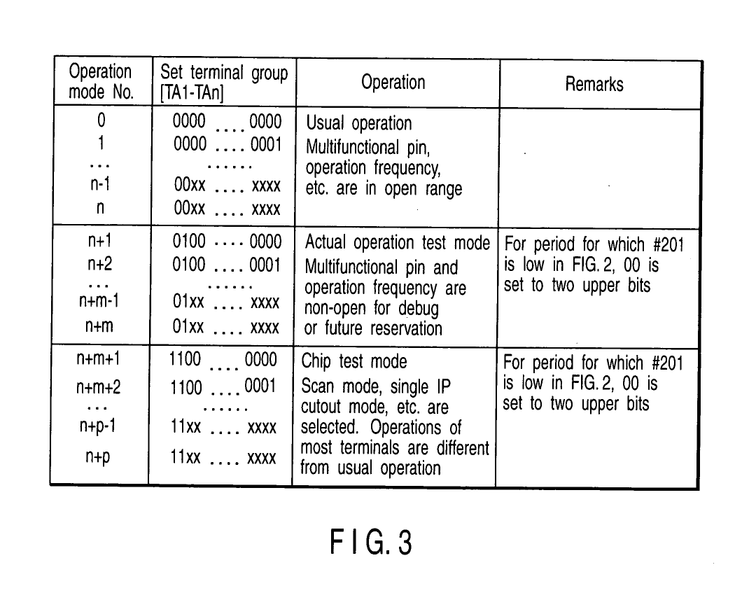

FIG. 3 is a diagram showing one example of the operation mode set to the LSI 300.

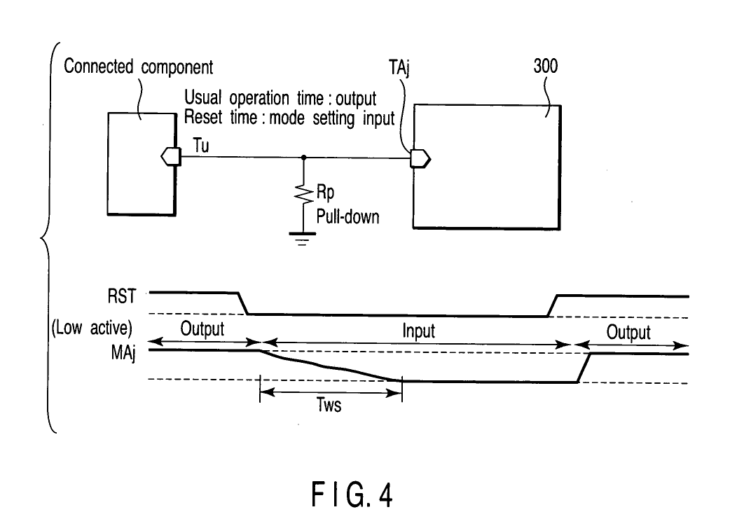

Modes of operation mode numbers 0 to n are usual operation modes usable by a user, and both of two upper bits, that is, terminals MA1, MA2 are set to 0. The user determines a desired operation mode to pull up or pull down a wiring line on a board connected to the terminals TA1 to TAn corresponding to the operation mode by use of a resistance element. For example, when the LSI 300 is to be set to the operation mode number 0, all wiring line patterns connected to the terminals TA1 to TAn are connected to GND via the resistance element as shown in FIG. 4. Alternatively, when the LSI 300 is to be set to the operation mode number 1, the wiring line pattern connected to the terminal TAn is connected to a power supply via the resistance element, and the wiring line patterns connected to the other terminals TA1 to TAn-1 are connected to GND via the resistance element.

Modes of operation mode numbers n+1 to n+p are test modes which are used by a designer of the LSI, and one or both of two upper bits, that is, the terminals MA1, MA2 is set to 1. An operation in the test modes is not described at all in product specifications, and is a non-open operation. The designer determines a desired test mode, and signals corresponding to the test mode are supplied to the terminals TA1 to TAn during system reset.

Description will be made returning to FIGS. 1 and 2. While the signal #201 is at the L level (t1 to t3), two upper bits of the mode setting input signal are fixed to a usual operation mode (0, 0) by the logical circuits 110a, 110b. That is, even when signals (signals including 1 in two upper bits) indicating the test mode are input as a signal group A, both of the logical circuits 110a, 110b output 0. As a result, for a period Tdm (t2 to t3), the flip-flops 108a to 108n output an arbitrary mode in the usual operation mode to the LSI main body unit 200.

For the next period Ttm (t3 to t4), the signal #201 is at the H level, and the signal #202 is at the L level. Therefore, the selectors 109a, 109b output values of the signals MA1, MA2 input into the terminals TA1, TA2 as they are. That is, for the period Ttm (t3 to t4), the flip-flops 108a to 108n output the operation mode (the original operation mode) input as the signal group A as it is. This original operation mode is held by the selectors 109a to 109n and the flip-flops 108a to 108n, until the system reset signal later becomes the active level as described above.

Next, various operation modes shown in FIG. 3 will be described.

The modes of the operation mode numbers 0 to n are the operation modes which are used by the user as described above, and they are the usual operation modes in which a multifunctional pin and the like are opened (e.g., specified in the product specifications). Here, the multifunctional pin is a terminal which can be in various operation modes, and functions as an input terminal or an output terminal in accordance with the set operation mode.

Modes of the operation mode numbers n+1 to n+m are actual operation test modes in which the LSI is mounted on a circuit substrate and which are used to test the operation described in the product specifications, and they are modes which are used by the designer of the LSI as described above. A multifunctional pin and an operation frequency in each of these modes are not opened.

Modes of the operation mode numbers n+m+1 to n+p are chip test modes in which the LSI is tested in the form of a single unit. These modes are also modes which are used by the designer of the LSI. In these modes, functional blocks constituting the LSI are individually tested.

Heretofore, to set the LSI to each of the test modes of the operation mode numbers n+1 to n+p, a TEST terminal (an exclusive terminal for the test mode) for indicating whether or not the selected mode is the test mode is disposed in addition to a usually usable terminal. After the TEST terminal has been set to, for example, a power supply voltage, test mode signals are input as the signal group A. Alternatively, to set the LSI to the test mode, the test mode signals are input by utilization of the system reset signal.

However, in the case of the LSI which sets the test mode by utilization of the system reset signal, the LSI temporarily becomes the test mode sometimes during the system reset as described later with reference to FIG. 4 during the usual operation by the user. Since the user is not notified of the operation mode other than the usual operation mode, the user designs a board (circuit board) of the system using the LSI without considering any operation in the actual operation test mode or the chip test mode. Therefore, when the LSI temporarily becomes the test mode during the usual operation as described above, the terminal assumed as the input terminal turns to the output terminal, or conversely, the output terminal turns to the input terminal. In such a case, another device or the LSI itself on the board might be broken. Therefore, it has been heretofore proposed that for a reset period, most terminals of the LSI be controlled into an input state as in the buffers 111a to 111n to protect the device, and the leads from the terminals are pulled-up or pulled-down on the user's board.

FIG. 4 is a diagram showing a behavior in which, for example, the LSI 300 is mounted onto the user's board, so that the system reset signal becomes active, the terminal group TG is set to the input terminals under control of the buffers 111a to 111n, and then a potential of a certain terminal TAj in the terminal group TG changes. A pull-down resistance Rp is a resistance element for setting the operation mode (operation mode numbers: 0 to n) for use by the user in FIG. 3. It is supposed that the terminal group TG is used as the output terminals in the usual operation mode. Therefore, it is assumed that an input terminal Tu of a component connected to the user's board is the input terminal, and an input resistance of the terminal is infinitely large.

A time (waiting time for stabilization of pull-up/down) Tws is required until the signal at the H level immediately before the system reset signal becomes the active level, lowers to the L level owing to the pull-down resistance Rp on the board, and the above time Tws also depends on a constant of the pull-down resistance. In general, the time Tws is in a range of about several hundreds of nanoseconds to 1 μs. It is to be noted that a similar time is also required at a time when a pull-up resistance is used.

For the operation mode update period Tmc (see FIG. 2B), the signals input from the terminals TA3 to TAn of the terminal group TG pass through the selectors 109c to 109n, and are sampled every period of the system clock signal CLK by the flip-flops 108c to 108n. Here, in a case where the system clock signal is 33 MHz, the operation mode is in an unstable state for a long period of 20 to 30 cycles after the reset (for the stabilization waiting time Tws).

Here, there is supposed a case where the logical circuits 110a, 110b disposed for two upper bits (MA1, MA2) of the mode setting signal (signal group A) are omitted as in the circuits (circuits including the buffers 111, selectors 109 and flip-flops 108) constituted for the other bits (MA3 to MAn). In this case, for the pull-up/down stabilization waiting time Tws, the operation mode can be the test mode. In the test mode, a large number of terminals are used as the multifunctional terminals in addition to the terminals for use as the multifunctional terminals in the usual operation mode. A behavior of each terminal in the test mode is non-open information which is not described in the product specifications. Therefore, the terminal for use as the multifunctional terminal only in the test mode needs to be controlled into the input state during the system reset and pulled up or down in the user's board as described above. This means increase in a board cost and increase in a size for the user.

As shown in FIG. 2, the reset signal RST becomes active at the time t1, and the mode till the time t1 for one clock cycle till the time t2 is selected by the selectors 109a to 109n. For the period of the time t2 to the time t3, both of the logical circuits 110a, 110b output 0, and this value is output from the flip-flops 108a, 108b through the selectors 109a, 109b. The period Tdm of the time t2 to the time t3 is a dummy mode selection period for which the arbitrary operation mode in the usual operation modes is selected as a dummy mode.

For the period Ttm of the time t3 to the time t4, the original mode (the test mode or the usual operation mode) input into the terminals TA1, TA2 is output from the logical circuits 110a, 110b as it is, and its value is selected at the time t4 by the selectors 109a, 109b and held by the flip-flops 108a, 108b. That is, for the period Ttm, the original operation mode is input into the flip-flops 108a to 108n, and the mode is held at and after the time t4 by the flip-flops 108a, 108b.

Therefore, only for the multifunctional terminal opened in the product specifications or the like, the user may take an appropriate measure on the board.

As described above, according to the present invention, there can be provided an operation mode setting circuit capable of setting the test mode/the usual operation mode of the LSI by use of the terminals for general applications (the reset input terminal 102 and the clock input terminal 103) without disposing any exclusive test mode setting terminal. Furthermore, in a case where the user uses the LSI 300 in the usual operation mode and when the reset signal is active, the LSI 300 does not become the test mode even temporarily. Therefore, it is possible to decrease pull-up or pull-down components for preventing a wrong operation of another device on the user's board connected to the terminal which becomes the multifunctional terminal only in the test mode.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An operation mode setting circuit which sets an operation mode of an LSI and which is disposed in the same chip as that of the LSI, the operation mode setting circuit comprising:
a first delay circuit which delays a system reset signal as much as one cycle of a clock signal;
a second delay circuit which delays the system reset signal as much as two cycles of the clock signals;
a mode terminal which inputs a mode signal indicating one of a usual operation mode and a test mode during system reset;
a logical circuit which performs a logical operation based on the mode signal input via the mode terminal and the system reset signal input into the first delay circuit;
a setting circuit which sets input/output of the mode terminal based on the system reset signal and an output signal of the second delay circuit;
a selection circuit having first and second input terminals, an output signal of the logical circuit being input into the first input terminal, the selection circuit being configured to select one of signals input into the first and second input terminals based on an output signal of the first delay circuit; and
a holding circuit which holds, based on the clock signal, the signal selected by the selection circuit and which supplies the held signal to the second input terminal of the selection circuit and which supplies the held signal as the mode signal to an LSI main body.

2. The operation mode setting circuit according to claim 1, wherein the logical circuit outputs a signal indicating the usual operation mode for a predetermined period during the reset, and after the predetermined period, the logical circuit outputs a value input into the mode terminal for a period of one cycle of the clock signal.

3. The operation mode setting circuit according to claim 1 or 2, wherein the logical circuit is an AND circuit.

4. The operation mode setting circuit according to claim 2, further comprising:
a plurality of second mode terminals which input operation setting signals to set an operation in the usual operation mode or the test mode during the system reset,
wherein for the predetermined period during the reset, an arbitrary operation mode in the usual operation mode is supplied to the LSI main body, and after the predetermined period, the mode input into the first and second mode terminals is supplied to the LSI main body.

5. An LSI including an LSI main body; and an operation mode setting circuit which sets an operation mode of the LSI main body,
the operation mode setting circuit comprising:
a first delay circuit which delays a system reset signal as much as one cycle based on a clock signal;
a second delay circuit which delays the system reset signal as much as two cycles based on the clock signal;
a mode terminal which inputs a mode signal indicating one of a usual operation mode and a test mode during system reset;
a logical circuit which performs a logical operation based on the mode signal input via the mode terminal and the system reset signal input into the first delay circuit;
a setting circuit which sets input/output of the mode terminal based on the system reset signal and an output signal of the second delay circuit;
a selection circuit having first and second input terminals, an output signal of the logical circuit being input into the first input terminal, the selection circuit being configured to select one of signals input into the first and second input terminals based on an output signal of the first delay circuit; and
a holding circuit which holds, based on the clock signal, the signal selected by the selection circuit and which supplies the held signal to the second input terminal of the selection circuit and which supplies the held signal as the mode signal to an LSI main body.

6. The LSI according to claim 5, wherein the logical circuit outputs a signal indicating the usual operation mode for a predetermined period during the reset, and after the predetermined period, the logical circuit outputs a value input into the mode terminal for a period of one cycle of the clock signal.

7. The LSI according to claim 6, further comprising:
a plurality of second mode terminals which input operation setting signals to set an operation in the usual operation mode or the test mode during the system reset,
wherein for the predetermined period during the reset, an arbitrary operation mode in the usual operation mode is supplied to the LSI main body, and after the predetermined period, the mode input into the first and second mode terminals is supplied to the LSI main body.

8. An operation mode setting method which sets an operation mode of an LSI, the method comprising:
inputting a mode signal indicating one of a usual operation mode and a test mode during system reset;
outputting a signal indicating the usual operation mode to the LSI for a predetermined period in response to the system reset signal; and
outputting, to the LSI, a value of the mode signal input during the system reset after the predetermined period.

9. The operation mode setting method according to claim 8, further comprising:
inputting operation setting signals to set an operation in the usual operation mode or the test mode during the system reset,
wherein for the predetermined period during the reset, an arbitrary operation mode in the usual operation mode is supplied to the LSI, and after the predetermined period, the mode input into the first and second mode terminals is supplied to an LSI main body.
